(19) United States
(12) Patent Application Publication
(10) Pub. No.: US 2012/0186632 A1
(43) Pub. Date: Jul. 26, 2012

(54) Mounting Assembly for Supporting a Solar Panel, and Method of Employing Same

(75) Inventors: Mark REINHOLD, Langhorne, PA (US); Frank J. CETTINA, Robbinsville, NJ (US)

(73) Assignee: COMPUTER COMPONENTS CORPORATION, Philadelphia, PA (US)

(21) Appl. No.: 13/357,683

(22) Filed: Jan. 25, 2012

Related U.S. Application Data
(60) Provisional application No. 61/461,949, filed on Jan. 25, 2011.

(51) Int. Cl. H01L 31/048; H01L 23/32; H01L 31/18

(52) U.S. Cl. 136/251; 29/890.033; 211/41.1

(57) ABSTRACT

A mounting assembly for a solar panel includes at least two laterally spaced-apart frames placed on a support surface. Each frame is selectively reconfigurable between an expanded configuration and a collapsed configuration. A spacer bracket extends generally perpendicularly to a longitudinal axis of each frame. Opposing ends of the spacer bracket are attached to a portion of one of the frame. A solar panel is supported by at least a portion of each frame. The solar panel is positioned at an angle of less than 90 degrees and greater than 0 degrees with respect to the support surface.

### CROSS-REFERENCE TO RELATED APPLICATION

The present application claims the benefit of U.S. Provisional Patent Application No. 61/461,949, filed Jan. 25, 2011 and entitled “Portable and Collapsible Assembly for Supporting a Solar Panel.”

### BACKGROUND OF THE INVENTION

The present invention is directed to a mounting assembly for a solar panel and, more particularly, to a portable and collapsible mounting assembly for supporting one or more solar panels generally at an incline or angle on a support surface, such as a roof top.

Solar panels, which convert photons or light energy from the sun into usable electricity, are well known and widely used. Solar panels may be referred to as photovoltaic modules or panels, and each generally includes a plurality of photovoltaic cells therein for converting light energy into usable or consumable energy. To ensure proper functionality, it is important to protect the photovoltaic cells from mechanical damage during transport, installation and use of the solar panels. The photovoltaic cells must also be protected from moisture, which corrodes metal contacts and interconnections of the cells, thus decreasing performance and life span of each solar panel.

Conventionally, after raising or hoisting one or more solar panels up to and on the roof top of a building, for example, roofers or other solar panel installers construct a rather cumbersome apparatus by hand to support the solar panels in the desired inclined position. This labor performed on the roof by the roofers or other solar panel installers can be time consuming and can significantly increase the cost of installing solar panel systems.

Therefore, a need exists for a portable, collapsible, compact and easy-to-assemble system for supporting one or more solar panels on a support surface, such as the roof of a building. Such a system would reduce the overall time required to install solar panels and, therefore, would reduce the overall cost of such systems. The present invention accomplishes these objectives.

### BRIEF SUMMARY OF THE INVENTION

Briefly stated, a preferred embodiment of the present invention is directed to a mounting assembly for a solar panel having at least two laterally spaced-apart frames placed on a support surface. Each frame is selectively reconfigurable between an expanded configuration and a collapsed configuration. A spacer bracket extends generally perpendicularly to a longitudinal axis of each frame. Opposing ends of the spacer bracket are attached to a portion of each frame. A solar panel is supported by at least a portion of each frame. The solar panel is positioned by the frames at an angle of less than 90 degrees and greater than 0 degrees with respect to the support surface.

In another aspect, a preferred embodiment of the present invention is directed to a method of employing a mounting assembly for a solar panel, including placing a first frame on a support surface, placing a second frame on the support surface, and aligning the frames such that a longitudinal axis of each frame extends generally parallel to one another. The method also includes aligning the frames to be laterally spaced-apart by a predetermined distance, rotating a clip of each frame to a raised position, and placing a solar panel on a top surface of at least a portion of each frame such that at least a portion of the solar panel is positioned within at least a portion of each clip.

In yet another aspect, a preferred embodiment of the present invention is directed to a frame for supporting at least a portion of a solar panel on a support surface. The frame includes a base truss having a first end and an opposing second end. A support truss has a first end, an opposing second end, a generally planar central portion and two spaced-apart side walls extending generally perpendicularly from opposing sides of the central portion. At least one of the side walls of the support truss proximate to the second end has a generally elongated slot that extends therethrough proximate the second end of the support truss. The first end of the base truss is pivotally attached to the first end of the support truss. A prop truss has a first end and opposing second end. The second end of the base truss is pivotally attached to the second end of the prop truss. A movable pin extends outwardly from the prop truss proximate the first end thereof. The movable pin is rotatably and slidably positioned within the generally elongated slot of the support truss.

### BRIEF DESCRIPTION OF THE SEVERAL VIEWS OF THE DRAWINGS

The foregoing summary, as well as the following detailed description of a preferred embodiment of the invention, will be better understood when read in conjunction with the appended drawings. For the purpose of illustrating the invention, there is shown in the drawings an embodiment which is presently preferred. It should be understood, however, that the invention is not limited to the precise arrangements and instrumentalities shown. In the drawings:

FIG. 1 is a rear perspective view of a partially assembled mounting assembly for a solar panel in accordance with a preferred embodiment of the present invention;

FIG. 2 is a magnified rear perspective view of a frame in an expanded configuration of the mounting assembly of FIG. 1;

FIG. 3 is a rear perspective view of the frame of FIG. 2 in a collapsed configuration;

FIG. 4 is a magnified perspective view of a spacer bracket of the mounting assembly of FIG. 1;

FIG. 5 is magnified left side perspective view of one frame of the mounting assembly of FIG. 1 in the expanded configuration;

FIG. 6 is a front perspective view of multiple frames and spacer brackets in an assembled configuration, and a plurality of ballasts positioned within the frames and spacer brackets of FIG. 1; and

FIG. 7 is a magnified perspective view of a portion of the frames, spacer brackets and ballasts of FIG. 6.

### DETAILED DESCRIPTION OF THE INVENTION

Certain terminology is used in the following description for convenience only and is not limiting. The words “lower,” “bottom,” “top,” and “front” designate directions in the drawings to which reference is made. The word “outwardly” refers to a direction away from the geometric center of the device, and designated parts thereof, in accordance with the present invention. Unless specifically set forth herein, the terms “a,” “an” and “the” are not limited to one element, but instead should be read as meaning “at least one.” The terminology includes the words noted above, derivatives thereof and words of similar import.

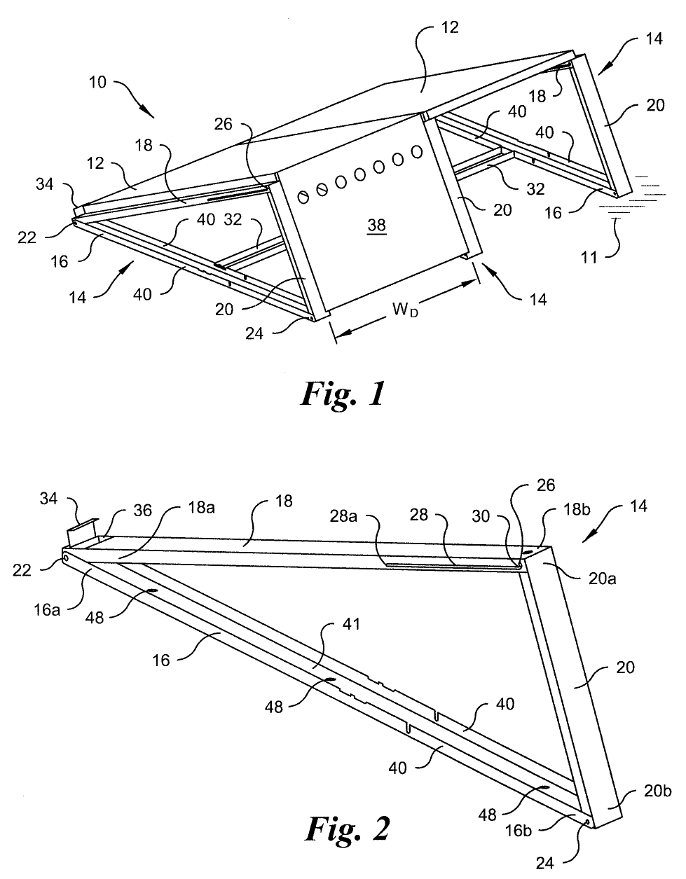

Referring to the drawings in detail, wherein like numerals indicate like elements throughout, FIGS. 1-7 show a mounting assembly, generally designated 10, for supporting one or more solar panels 12 (shown schematically) on a support surface 11. The mounting assembly 10 is generally a combination of trusses beams, at least some of which are preferably movable, expandable and/or collapsible to support one or more solar panels 12 at an incline or angle with respect to the support surface 11. The angle is preferably less than 45 degrees, such as 20 degrees, with respect to the support surface 11. Such an angle maximizes operational effectiveness of the solar panel(s) 12. However, the angle may be any angle generally less than perpendicular (90 degrees) and generally greater than parallel (0 degrees) with respect to the support surface 11.

The support surface 11 is preferably a top surface of a roof of a building or home, but the mounting assembly 10 of the present invention may be employed on nearly any surface that is capable of supporting the weight of one or more solar panels 12. For example, the mounting assembly 10 could be employed on top of a parking garage or even on a parking lot at ground level. The components of the mounting assembly 10 are preferably formed of a light-weight, high-strength material, such as steel or aluminum sheet metal that is easily manufactured in a rolled form. As is evident from the features described in detail below, the assembly 10 is preferably a portable and durable support apparatus for safely, securely and stably supporting one or more solar panels 12 at a desired incline position.

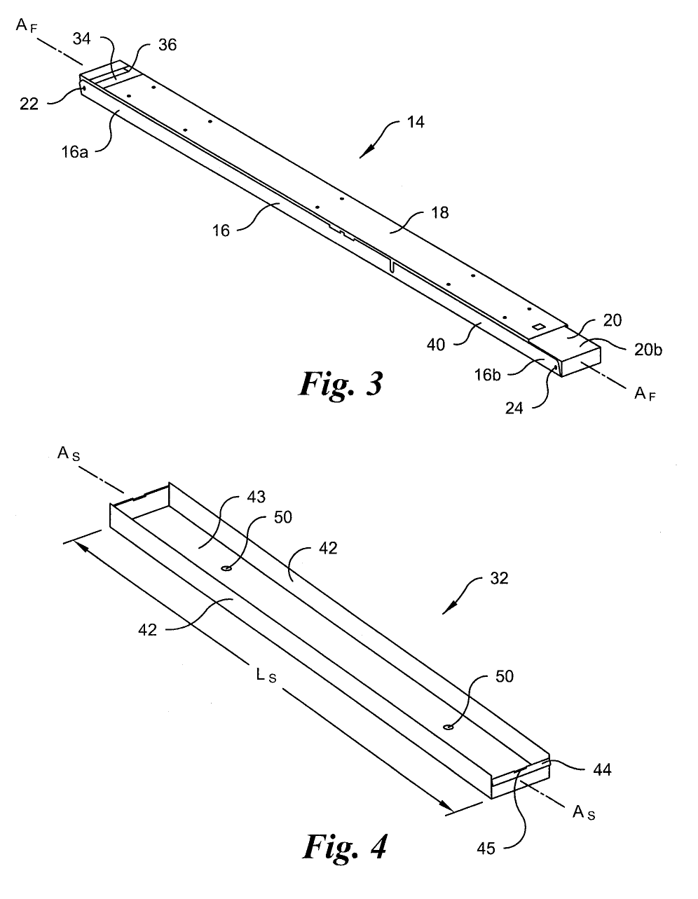

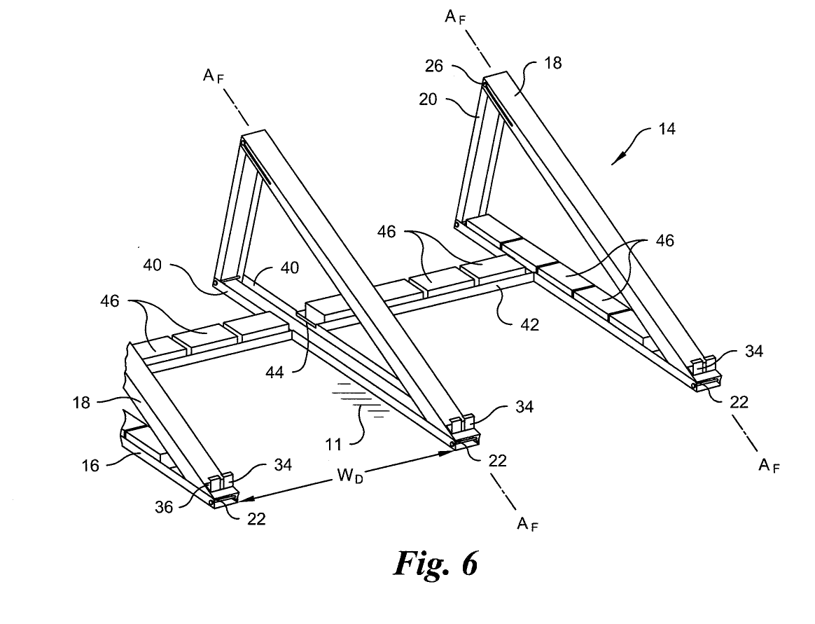

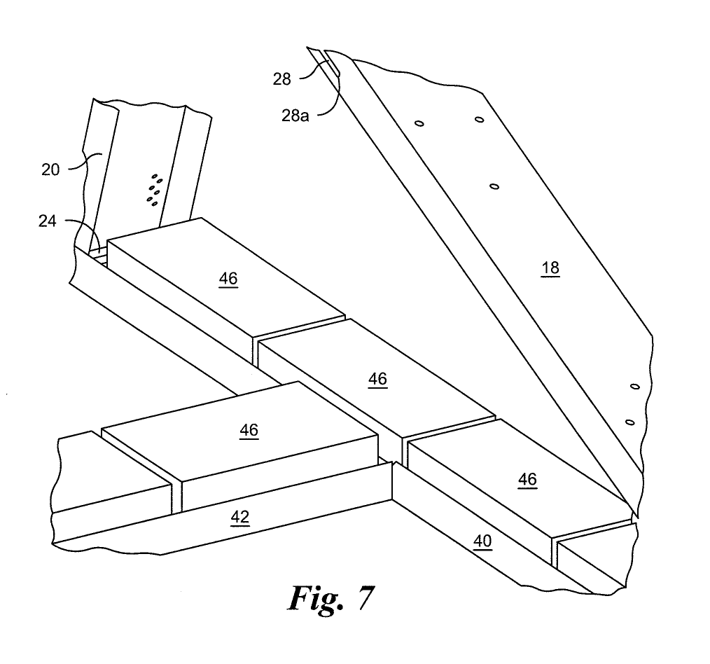

Referring to FIGS. 1-3, and 6, the assembly 10 preferably includes at least two laterally spaced-apart frames, each generally designated 14. Each frame 14 is preferably selectively foldable, collapsible or pivotable to move between an expanded or unfolded configuration (FIGS. 1, 2 and 5-7), for supporting one or more of the solar panels 12 in an incline position, and a collapsed or folded configuration (FIG. 3), for ease of storage and/or transport. It is preferred that adjacent frames 14 are generally laterally spaced-apart at a distance generally equal to, but preferably at least slightly less than, the width W_{D} (FIGS. 1 and 6) of a solar panel 12, so as to directly engage and support at least opposing sides of the solar panel 12. A limitless number of frames 14 may be used to support a limitless number of solar panels 12, as suggested in FIG. 6. In use, the frames 14 are preferably placed or laid on the support surface 11 such that a longitudinal axis A_{F} (see FIGS. 3 and 6) of each extends generally parallel to one another.

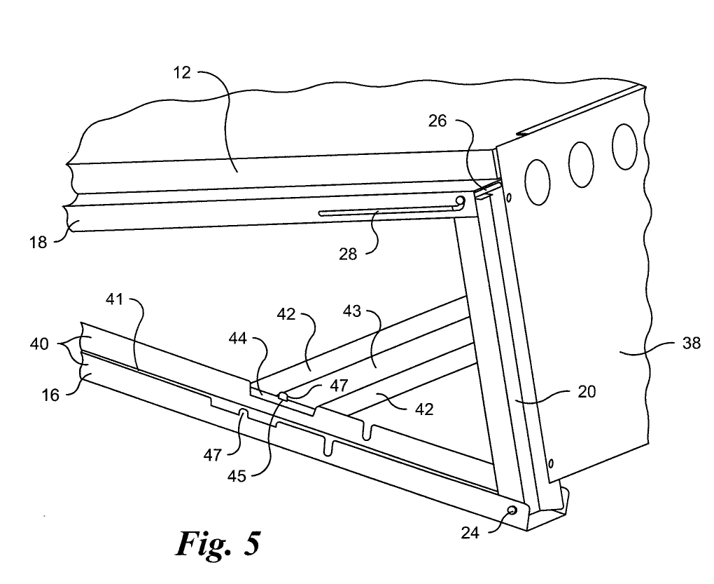

Referring specifically to FIGS. 1-3, each frame 14 preferably includes a first or base truss 16, a second or support truss 18 and a third or prop truss 20. Each truss 16, 18, 20 of each frame 14 is preferably generally U-shaped in lateral cross-section. In other words, each truss 16, 18, 20 of each frame 14 includes a generally flat or planar central portion 41 defining a plane that extends generally perpendicularly, and preferably exactly perpendicularly, to two laterally spaced-apart side walls 40. FIGS. 1-3 and 5-7 show the side walls 40 of the base truss 16, and FIGS. 2 and 5 show the central portion 41 of the base truss 16. The support truss 18 and prop truss 20 have similarly sized and shaped side walls and a central wall, as readily understood by those of ordinary skill in the art. In the expanded configuration (FIG. 2), at least a midsection of each truss 16, 18, 20 of each frame 14 is preferably spaced-apart. In the collapsed configuration (FIG. 3), the support truss 18 and the prop truss 20 of each frame 14 are preferably in engagement with and generally fit within the base truss 16 thereof.

The distance between each side wall 40 of at least the base truss 16 is preferably at least slightly greater than the width (approximately four inches) of a conventional masonry or ceramic rectangular brick 46, for example, as shown in FIGS. 6 and 7. Due to the generally U-shaped configuration of each base truss 16, a plurality of conventional bricks 46 or other ballast may be laid in an abutting end-to-end configuration, for example, in the central portion 41 of each base truss 16 and/or spacer bracket 32 (described in detail below), and between the side walls 40 of each base truss 16 and/or spacer bracket 32 along the length of each base truss 16 and/or spacer bracket 32. The size and shape of each base truss 16 is therefore capable of receiving ballast weight 46 to provide sufficient mass to the assembly 10 to firmly hold the assembly 10 on the support surface 11 without the need for fixing the assembly 10 directly to the support surface 11, such as by conventional bolts, screws or nails (none shown). The ballast weight 46 is not limited to one or more conventional rectangular bricks, but may be any structure or device in any size or shape capable of adding weight to the assembly 10. Of course, the ballast weight 46 may be selectively removed and/or repositioned within each the base truss 16 of each frame 12, for example, as desired.

As shown specifically in FIG. 2, a first end 16a of the base truss 16 is preferably pivotally attached to a first end 18a of the support truss 18. More specifically, it is preferred that a conventional dowel-like first pin 22 preferably extends through suitably sized aligned holes and pivotally attaches the first end of 16a of the base truss 16 to the first end 18a of the support truss 18. Similarly, it is preferred that an opposing second end 16b of the base truss 16 is pivotally attached to a second end 20b of the prop truss 20. More specifically, it is preferred that a dowel-like second pin 24 preferably extends through suitably sized aligned holes and pivotally attaches the second end 16b of the base truss 16 to the second end 20b of the prop truss 20 in the expanded configuration. Likewise, a second end 18b of the support truss 18 is preferably pivotally attached to a first end 20a of the prop truss 20. More specifically, it is preferred that a dowel-like moveable third pin 26 preferably extends through suitably sized aligned holes and pivotally attaches the second end 18b of the support truss 18 to the first end 20a of the prop truss 20. Opposing end portions of each pin 22, 24, 26 may include an enlarged portion, lip or ledge that generally maintains each pin 22, 24, 26 in the desired position and/or location and prevents each pin 22, 24, 26 from inadvertently or undesirably sliding out of a respective hole or slot. The pins 22, 24, 26 are not limited to a dowel-like shape and/or configuration, but may be any shape or object capable of allowing pivoting or folding motion, such as a conventional bolt or cotter pin. The pins 22, 24, 26 may be rotatably attached to one of the trusses 16, 18, 20, or one or more of the pins 22, 24, 26 may be completely removable from the trusses 16, 18, 20 and may be inserted into the corresponding aligned holes after the frame 14 is arranged in the expanded configuration.

As shown in FIG. 3, each frame 14 is preferably collapsible into the size and shape of approximately a 2 in. by 4 in. wood beam. To allow for such movement, it is preferred that at least a portion of the moveable pin 26 is sized and shaped to movably or slidably fit within a generally elongated slot or groove 28 formed in the side walls of the support truss 18. The slot 28 is preferably formed in at least one and possibly both of the side walls of the support truss 18 proximate the second end 18b of the support truss 18 and extends generally parallel to the longitudinal axis A_{F} of the support truss 18. A first end 28a of the slot 28 proximate a longitudinal mid-section of the support truss 18 is preferably generally at least partially circular in shape. An opposing second end 28b of the slot 28 proximate the second end 18b of the support truss 18 is preferably at least partially an eccentrically-shaped and enlarged notch 30. In operation, when a portion of the moveable pin 26 is positioned within the notch 30, the frame 14 is generally held or locked in the expanded, unfolded or open configuration (see FIGS. 1, 2 and 5-7). When a respective frame 14 is positioned in the expanded configuration, a bottom surface of the central portion 41 of the base truss 16 extends preferably parallel and directly engages the support surface 11, and each of the support truss 18 and prop truss 20 generally support the weight of generally one or more solar panels 12 above the support surface 11.

As mentioned above, and referring to FIGS. 1 and 4, the assembly 10 preferably includes at least one and preferably two or more spacer brackets 32 that preferably removable attach to and extend between the base truss 16 of adjacent and laterally spaced-apart frames 14. A length L_{S} (FIG. 4) of each spacer bracket 32, as measured from opposing ends of the spacer bracket 32 along a longitudinal axis A_{S} (FIG. 4) thereof, is preferably at least slightly less than the width W_{D} (FIG. 1) of a single solar panel 12. In particular, it is preferred that in the assembled configuration (FIG. 1), each solar panel 12 extends over approximately half of the width of a corresponding support truss 18 so that the solar panel 12 is stably supported on the support truss 18. In other words, any one solar panel 12 is preferably considered “on-center” with respect to two support trusses 18.

Each spacer bracket 32 is also preferably generally U-shaped, as described above with respect to each truss 16, 18, 20. FIGS. 4 and 5 show the spacer bracket 32 having a preferably generally flat or planar central portion 43 and two spaced-apart side walls 42 extending at least generally perpendicularly from opposing side edges of the central portion 43. As described above, the cross-sectional generally U-shape allows for removable receipt of one or more conventional bricks 46 to provide ballast weight to the assembly 10. The spacer brackets 32 are preferably selectively attachable and detachable directly to the frames 14 without the use of tools, such as a hammer or a drill. Specifically, it is preferred that opposing ends of each spacer bracket 32 include a hook or lip 44 (see FIGS. 4-6), for example, that extends at least slightly outwardly from opposing ends of each spacer bracket 32 and is sized and shaped to receive at least a portion one of the side walls 40 of the base truss 16 of each frame 14. As shown in FIG. 5, each hook 44 may include an opening 45 that extends completely therethrough and is sized and/or shaped to at least partially receive a projection 47 on one of the side walls 40 of the base truss 16. The combination of the opening 45 and the projection 47 creates a more secure connection between the spacer bracket 32 and one of the base trusses 16.

Referring to FIGS. 1-3 and 6, a front end of each frame 14, or a lower or front end 18a of each support truss 18, preferably includes a selectively rotatable clip 34. The clip 34 is preferably rotatable with respect to the support truss 18 between a folded or compact position (FIG. 3) for storage and/or transport of the frame 14, and a raised, unfolded or expanded position (FIGS. 1, 2 and 6) for receiving at least a portion of the solar panel 12 and supporting the solar panel 12 on the support truss 18. The clip 34 may be pivotable or rotatable about a pin or shaft, such as the first pin 22, rotatably or fixedly attached to the support truss 18. The central portion of each support truss 18 preferably defines an opening 36 proximate the first end 18a of the support truss 18. The opening 36 is preferably sized and shaped to receive the clip 34 in the folded position, and also provides a passageway for an installer to at least partially grasp the clip 34 with his/her fingers, so as to rotate the clip 34 to the raised position. The clip 34 is preferably sized and shaped to fit entirely within the opening 36 to aid in creating a compact frame 14 when in the collapsed configuration.

As shown in FIG. 2, the clip 34 generally defines a hook or L-shaped structure in the expanded position (FIGS. 1, 2 and 6) and at least a portion of the clip 34 extends above the central wall of the base truss 18 when the clip 34 is in the expanded position. The thickness of each solar panel 12 is preferably slightly less than a dimension (i.e., width) of the L-shaped clip 34, such that at least a portion (i.e., bottom portion) of a solar panel 12 can be received between the central portion of the support truss 18 and the clip 34 in the expanded position. The clip 34 is thus sized and shaped to receive at least a portion of a solar panel 12 therein (see FIG. 1). In the expanded position, the clip 34 generally fixes the solar panel 12 in the desired position on the frame 14 and prevents the solar panel 12 from sliding down the support truss 18 and contacting the support surface 11. It is understood that the clip 34 is not limited to being rotatable or pivotable, but may alternatively be fixed in place on the support truss 18, for example.

Referring to FIGS. 1 and 5, a wind deflector 38 is preferable selectively removably attachable to at least a portion of each prop truss 20 of adjacent frames 14. The wind deflector 38 is generally a flat or planar object having a width W_{D} (FIG. 1) that is preferably at least slightly greater than the length L_{S} (FIG. 4) of any spacer bracket 32, so that at least opposing lateral sides of the wind deflector 38 overlap the side walls of the prop truss 20. The wind deflector 38 preferably includes at least one or a series of spaced-apart through holes for allowing air or wind to flow therethrough. The wind deflector 38 is preferably attachable and detachable to one or more frames 14 without the use of tools, such that the wind deflector 38 preferably clips or snaps onto one or more prop trusses 20 and/or a portion of the solar panel 12. FIG. 1 only shows one wind deflector 38 attached to an adjacent pair of frames 14, but a second wind deflector 38 may also be attached to the other pair of adjacent frames 14, such that two or more wind deflectors 38 may be established in a side-by-side configuration. The wind deflector 38 preferably dampens the effect of strong winds on the fully assembled and unfolded mounting assembly 10. In addition, in combination with at least one unfolded clip 34, a top portion of the wind deflector 38 extends around, clamps and/or sandwiches at least a portion (i.e., top or proximal portion) of a solar panel 12 on top of a support truss 18. The combination of clips 34 and wind deflector(s) 38 generally lock a solar panel 12 in a desired position without the use of tools or supplemental fasteners.

A method of employing the mounting assembly 10 includes placing one of the frames 14 on the support surface 11 and placing another one of the frames 14 on the support surface 11. It is preferred that the frames 14 are aligned such that the longitudinal axis A_{F} of each of the two frames 14 extends generally parallel to one another. The two frames 14 are also preferably aligned to be laterally spaced-apart at a distance preferably at least slightly less than the width W_{D} of one of the solar panels 12, such a distance could equal width W_{D} minus four inches. The clip 34 of each frame 34 is preferably rotated to a raised position, and one of the solar panels 12 is preferably placed on a top surface (i.e., support truss 18) of at least a portion of the two frames 14, such that at least a portion of the solar panel 12 is positioned within at least a portion of each clip 34. Simultaneously or subsequent to the above, a separate third frame 14 may be placed on the support surface 11 in a parallel and spaced-apart configuration from either of the two adjacent frame 14. The clip 34 of the third frame 14 can be rotated to a raised position, and a second solar panel 12 can be placed on the top surface (i.e., support truss 18) of at least a portion of the third frame 14 and one of the first and second frames 14, such that at least a portion of the second solar panel 12 is positioned within at least a portion of the clip 34 of both the third frame 14 and one of the first and second frames 14. At any time during the above process, each frame 14 may be expanded from the collapsed configuration (FIG. 3) to the expanded configuration (FIG. 2).

In the fully assembled and unfolded configuration, the assembly 10 is preferably not screwed, riveted or otherwise fixed to the support surface. Thus, the assembly 10 can be quickly installed without the use of tools. Instead, as described above, conventional bricks 46 are preferably placed between opposing side walls 40 of one or more base trusses 16 and/or between opposing side walls 42 of each spacer bracket 32. The bricks 46 preferably provide the necessary ballast weight to prevent the assembly 10 from unnecessarily moving on top of the support surface 11, and the bricks 46 alleviate the need to undesirably drill or hammer directly into the support surface 11.

In the collapsed form, each frame 14 and each spacer bracket 32 is capable of being conveniently stacked and/or aligned on a conventional wooden pallet (not shown) in a compact manner. As a result, multiple collapsed assemblies 10 can be stored, shipped and/or transported in bulk due to the collapsibility, size and shape of each assembly 10. The spacer brackets 32 and collapsed frames 14 are also relatively light-weight and compact for ease of hoisting or raising from a ground surface, for example, up to a roof top, for example. As a result, the difficult and time-consuming task of raising, hoisting or transporting heavy and awkward conventional solar panel support structures to a roof top is alleviated. The quick and easy unfolding or expanding capability of each frame 14 drastically reduces the time required to construct the necessary support for each solar panel 12 on the roof top.

While it is preferred that the frames 14 and spacer brackets 32 do not include predefined openings for receiving fasteners, any portion of the frames 14 and/or spacers 32 may include pre-drilled openings 48, 50 to receive one or more generally elongated fasteners (not shown), such as a bolt, screw or nail, for applications in high-wind environments. For example, as shown in FIGS. 2 and 4, the planar central portion 41 of the base truss 16 and/or the planar central portion 43 of the spacer bracket 32 may include one or more spaced-apart mounting holes 48, 50, respectively, extending completely therethrough. Each mounting hole 48, 50 is preferably sufficiently sized and shaped to receive at least a shaft of a fastener therethrough. In locations that may experience high winds or on a non-level support surface, for example, it may be desirable to securely fasten the base truss 16 and/or spacer bracket 32 to the support surface 11 may inserting one or more fasteners through the base truss 16 and/or spacer bracket 32 and into the support surface 11. Doing so can be in place of, or in addition to, the ballast weight 46 described above.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A mounting assembly for a solar panel, the assembly comprising:
at least two laterally spaced-apart frames placed on a support surface, each frame being selectively reconfigurable between an expanded configuration and a collapsed configuration;
a spacer bracket extending generally perpendicularly to a longitudinal axis of each frame, opposing ends of the spacer bracket being attached to a portion of each frame; and
a solar panel supported by at least a portion of each frame, the solar panel being positioned by the frames at an angle of less than 90 degrees and greater than 0 degrees with respect to the support surface.

2. The assembly according to claim 1 wherein each frame includes a base truss, a support truss and a prop truss, a first pin pivotally attaches a first end of the base truss to a first end of the support truss, a second pin pivotally attaches a second end of the base truss to a second end of the prop truss, and a movable third pin pivotally attaches a second end of the support truss to a first end of the prop truss.

3. The assembly according to claim 2 wherein at least a portion of the movable third pin is sized and shaped to fit within an elongated slot in at least one side wall of the support truss.

4. The assembly according to claim 3, wherein one end of the slot includes an enlarged notch, and wherein each frame is held in the expanded configuration when at least a portion of the movable pin is positioned in the enlarged notch.

5. The assembly according to claim 2, wherein in the expanded configuration at least a midsection of each truss of each frame is spaced-apart, and wherein in the collapsed configuration the support truss and the prop truss of each frame are in engagement with and generally fit within the base truss thereof.

6. The assembly according to claim 2 further comprising:
a wind deflector attached to at least a portion of the prop truss of each frame, at least a portion of the wind deflector being sized and shaped to receive and hold at least a portion of the at least one solar panel.

7. The assembly according to claim 1 further comprising:
a clip rotatably attached to one end of the support truss of each frame, the clip being sized and shaped to receive and hold at least a portion of the at least one solar panel.

8. The assembly according to claim 1 further comprising:
a ballast removably positioned within at least a portion of one of the frames or in the at least one spacer bracket.

9. A method of employing a mounting assembly for a solar panel, the method comprising:
placing a first frame on a support surface;
placing a second frame on the support surface;
aligning the first and second frames such that a longitudinal axis of each frame extends generally parallel to one another;
aligning the first and second frames to be laterally spaced-apart by a predetermined distance;
rotating a clip of each of the first and second frame to a raised position; and
placing a solar panel on a top surface of at least a portion of each of the first and second frames such that at least a portion of the solar panel is positioned within at least a portion of each clip.

10. The method according to claim 9, further comprising:
expanding each of the first and second frames from a collapsed configuration to an expanded configuration.

11. The method according to claim 9, further comprising:
attaching a wind deflector to at least a portion of each of the first and second frames.

12. The method according to claim 9, further comprising:
placing ballast within at least a portion of one of the first and second frames after expanding the frame from a collapsed configuration to an expanded configuration.

13. The method according to claim 9, further comprising:
inserting a fastener through a mounting hole of each of the first and second frames and at least partially into the support surface.

14. A frame for supporting at least a portion of a solar panel on a support surface, the frame comprising:
a base truss having a first end and an opposing second end;
a support truss having a first end, an opposing second end, a generally planar central portion and two spaced-apart side walls extending generally perpendicularly from opposing sides of the central portion, at least one of the side walls of the support truss proximate to the second end having a generally elongated slot that extends therethrough proximate the second end of the support truss, the first end of the base truss being pivotally attached to the first end of the support truss; and
a prop truss having a first end and opposing second end, the second end of the base truss being pivotally attached to the second end of the prop truss, a movable pin extending outwardly from the prop truss proximate the first end thereof, the movable pin being rotatably and slidably positioned within the generally elongated slot of the support truss.

15. The frame according to claim 14 at least one ballast removably positioned within at least a portion of the base truss.

16. The frame according to claim 14 wherein a first pin pivotally attaches the first end of the base truss to the first end of the support truss, and wherein a second pin pivotally attaches the second end of the base truss to the second end of the prop truss.

17. The frame according to claim 14 wherein the frame is selectively reconfigurable between an expanded configuration and a collapsed configuration, the base truss extending generally parallel to the support truss and the prop truss in the collapsed configuration, the support truss extending at an angle between 90 degrees and 0 degrees with respect to the base truss in the expanded configuration.

18. The frame according to claim 17 wherein one end of the generally elongated slot includes an enlarged notch, and wherein the frame is held in the expanded configuration when at least a portion of the movable pin is positioned in the enlarged notch.

19. The frame according to claim 18, wherein in the expanded configuration at least a midsection of each truss of the frame is spaced-apart, and wherein in the collapsed configuration the support truss and the prop truss of the frame are in engagement with and generally fit within the base truss.

20. The frame according to claim 14 further comprising:
a clip rotatably attached to one end of the support truss, the clip being sized and shaped to receive and hold at least a portion of a solar panel.
